(19) United States
(12) Patent Application Publication
(10) Pub. No.: US 2013/0234184 A1
(43) Pub. Date: Sep. 12, 2013

(54) LIGHT EMITTING DIODE PACKAGE AND METHOD OF MANUFACTURING THE SAME

(71) Applicants: PIN-CHUAN CHEN, Hukou (TW); HSIN-CHIANG LIN, Hukou (TW)

(72) Inventors: PIN-CHUAN CHEN, Hukou (TW); HSIN-CHIANG LIN, Hukou (TW)

(21) Appl. No.: 13/650,088

(22) Filed: Oct. 11, 2012

(30) Foreign Application Priority Data
Mar. 8, 2012 (CN) 201210059622.2

(51) Int. Cl. H01L 33/50

(52) U.S. Cl. 257/98; 438/27; 257/E33.061

(57) ABSTRACT

An LED package includes a substrate, an LED chip mounted on the substrate. The LED chip has a side surface and an upper surface. A fluorescent layer is evenly distributed over the LED chip. An encapsulant covers the LED chip and the fluorescent layer. A method of manufacturing the LED package is also provided.

### BACKGROUND

1. Technical Field

The disclosure relates to light emitting diode (LED) packages, and particularly to an LED package with high heat dissipating capability and a method of manufacturing the LED package.

2. Discussion of Related Art

LEDs' many advantages, such as high luminosity, low operational voltage, low power consumption, compatibility with integrated circuits, easy driving, long term reliability, and environmental friendliness have promoted their wide use as a lighting source.

Generally, an LED package includes an LED chip and an encapsulant arranged on the light emitting surface of the LED chip with fluorescent doped thereof. The encapsulant is formed by adhesive injection. However, it is difficult to control the height and the shape of the encapsulant via adhesive injection; as a result, the light emitted by the LED chip has a yellow halo and an uneven illumination.

Therefore, what is needed is an LED package which can overcome the described limitations.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a schematic, cross-sectional view of an LED package according to an exemplary embodiment of the present disclosure.

FIGS. 2 to 7 are cross-sectional views showing different steps of an embodiment of a method for manufacturing the LED package of FIG. 1.

### DETAILED DESCRIPTION OF EMBODIMENTS

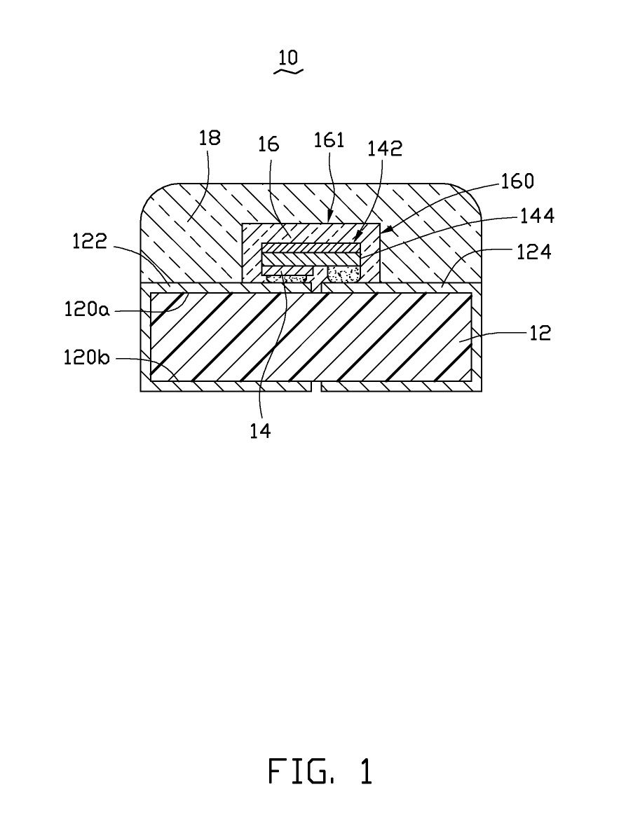

Referring to FIG. 1, an LED package 10 in accordance with an exemplary embodiment of the present disclosure is illustrated. The LED package 10 includes a substrate 12, an LED chip 14, a fluorescent layer 16 surrounding and covering the LED chip 14 and an encapsulant 18 surrounding and covering the fluorescent layer 16.

In the present embodiment, the substrate 12 is a rectangular plate and can be made of ceramic or silicon (Si). The substrate 12 includes a top surface 120a and a bottom surface 120b opposite to the top surface 120a. The substrate 12 has a first electrode 122 and a second electrode 124 formed thereon. The first electrode 122 and the second electrode 124 extend from the top surface 120a of the substrate 12 to the bottom surface 120b thereof along an outer edge of the substrate 12, whereby the LED package 10 is formed as a surface mounting type device.

The LED chip 14 is mounted on the first and second electrodes 122, 124 via a flip-chip technology. The LED chip 14 has a planar upper surface 142 away from the first and second electrodes 122, 124, and a side surface 144 perpendicular to the upper surface 142. In other embodiments, the LED chip 14 can be mounted on the first electrode 122 or the second electrode 124 via wire bonding.

The fluorescent layer 16 coats the upper surface 142 and the side surface 144 of the LED chip 14. The fluorescent layer 16 includes a first surface 161 away from the substrate 12 and an outer side surface 160 perpendicular to the first surface 161. In the present embodiment, the fluorescent layer 16 is evenly distributed over the LED chip 14.

A distance between the first surface 161 of the fluorescent layer 16 and the upper surface 142 of the LED chip 14 is equal to a distance between the outer side surface 160 and the side surface 144 of the LED chip 14.

The encapsulant 18 is arranged on the top surface 120a of the substrate 12 and covers the fluorescent layer 16 and part of the first and second electrodes 122, 124. The encapsulant 18 is formed of solidified silicone. In the present embodiment, a side surface of the encapsulant 18 is coplanar with an outer side surface of the first and second electrodes 122, 124, and a top surface of the encapsulant 14 is planar.

The fluorescent layer 16 is evenly distributed over the LED chip 14; therefore, the light color and the light emission of the LED package 10 can be substantially evenly distributed.

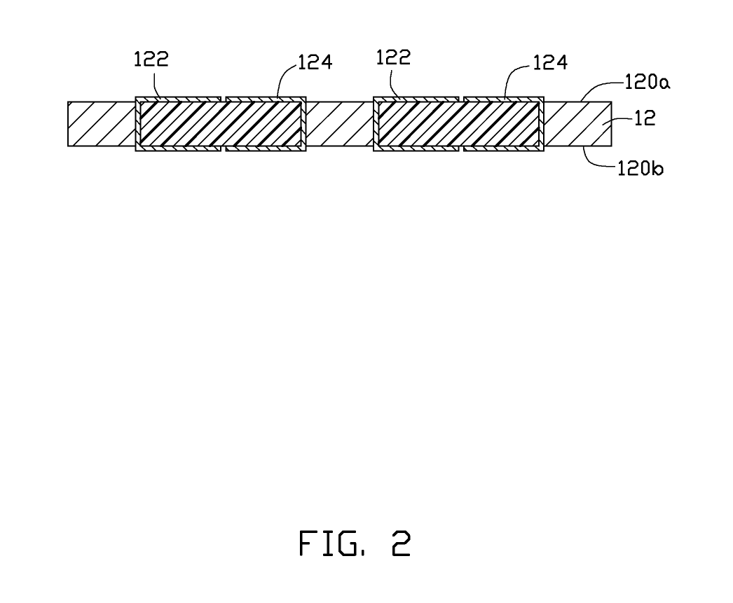

Referring to FIGS. 2-7, a method for manufacturing the LED package 10 in accordance with an exemplary embodiment is also disclosed. The method includes the following steps.

Step 1: referring to FIG. 2, a substrate 12 is provided, wherein the substrate 12 includes a top surface 120a and a bottom surface 120b opposite to the top surface 120a. In the present embodiment, the substrate 12 includes two first electrodes 122 and two second electrodes 124 formed thereon. Each first electrode 122 and each second electrode 124 extend from the top surface 120a of the substrate 12 to the bottom surface 120b thereof, whereby the LED package 10 is formed as a surface mounting type device.

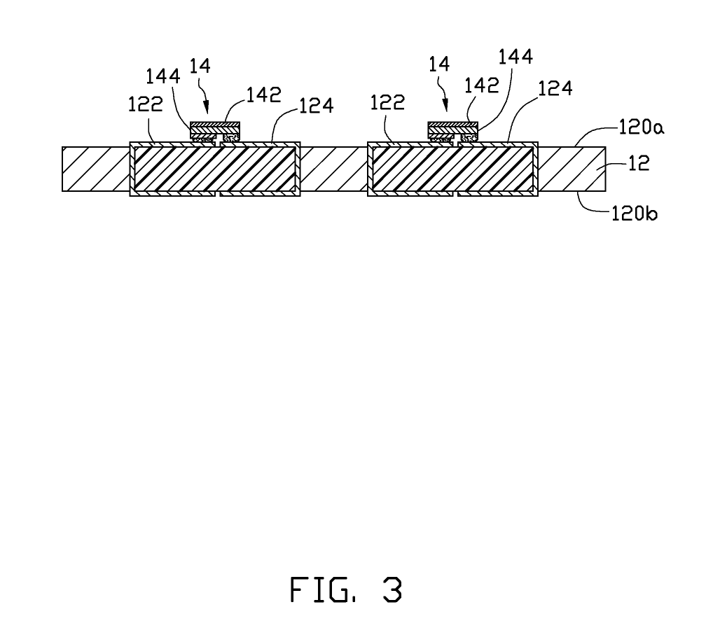

Step 2: referring to FIG. 3, two LED chips 14 are respectively mounted on the first and second electrodes 122, 124 via a flip-chip technology. The LED chip 14 has a planar upper surface 142 away from the corresponding first and second electrodes 122, 124, and a side surface 144 perpendicular to the upper surface 142. In other embodiments, the LED chip 14 can be mounted on the first electrode 122 or the second electrode 124 via wire bonding.

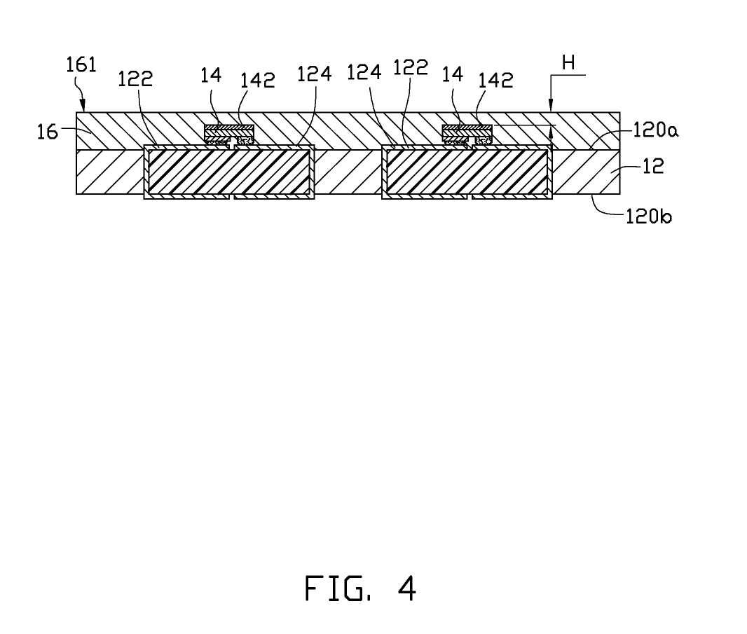

Step 3: referring to FIG. 4, a fluorescent layer 16 is formed on the top surface 120a of the substrate 12 and covers the LED chips 14 and part of the first and second electrodes 122, 124. In the present embodiment, the fluorescent layer 16 has a planar first surface 161 away from the substrate 12, and a height of the fluorescent layer 16 is larger than that of the LED chip 14. A distance between the upper surface 142 of the LED chip 14 and the first surface 161 of the fluorescent layer 16 is H.

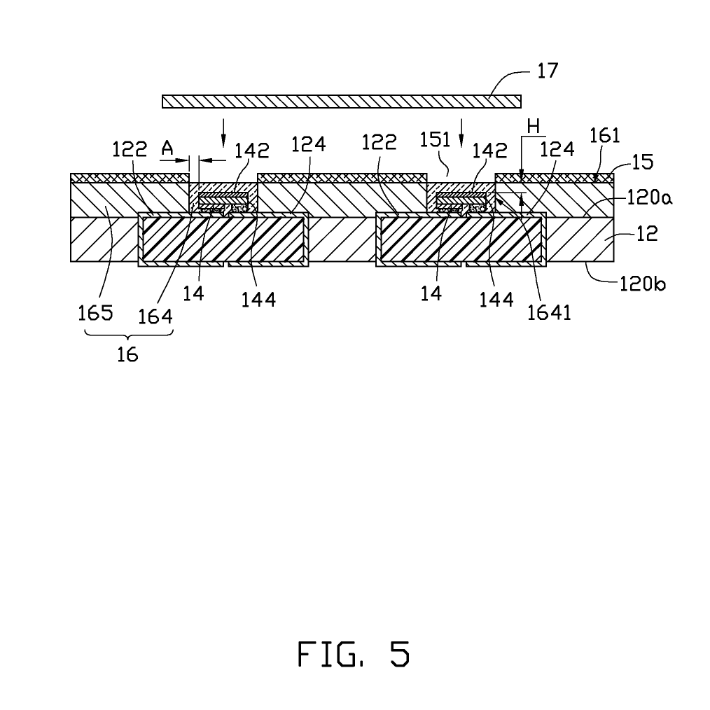

Step 4: referring to FIG. 5, a patterned mask 15 and an ultraviolet light source 17 is provided. The patterned mask 15 has a plurality of through holes 151 formed therein. The patterned mask 15 is arranged on the first surface 161 of the fluorescent layer 16. The fluorescent layer 16 includes first parts 164, each of which is just located above and surrounds an LED chip 14, and second parts 165 each of which is deviated from the corresponding LED chip 14 and connected to the first parts 164. Each of the first parts 164 is exposed to a corresponding through hole 151 of the patterned mask 15. In the present embodiment, each first part 164 of the fluorescent layer 16 has an outer side surface 1641, and a distance between the outer side surface 1641 of the first part 164 and the side surface 144 of the corresponding LED chip 14 is A. In the present embodiment, the distance A is equal to the distance H. The ultraviolet light source 17 irradiates through the through holes 151 of the patterned mask 15 to secure the first parts 164 of fluorescent layer 16.

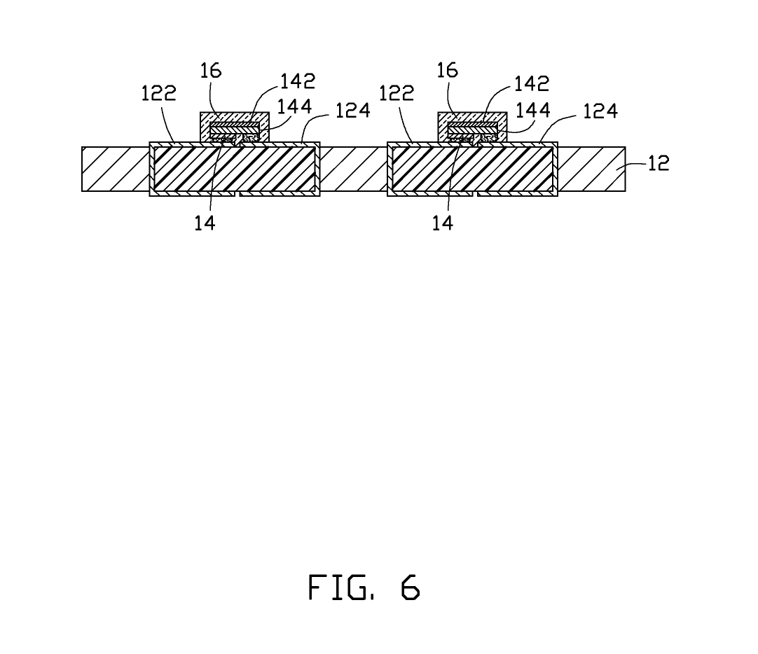

Step 5: referring to FIG. 6 also, the patterned mask 15 and the ultraviolet light source 17 are removed, and the second parts 165 of the fluorescent layer 16 are removed. In the present embodiment, the second parts 165 of the fluorescent layer 16 are removed via etching. The substrate 12, the LED chip 14, and the fluorescent layer 16 are submerged into solution, such as n-Heptanes, Toluene, Acetone and so on. The second parts 165 of the fluorescent layer 16 are not irradiated by the ultraviolet light source 17; thus, the second parts 165 of the fluorescent layer 16 dissolve in the solution and separated from the substrate 12. The first parts 164 of the fluorescent layer 16 are irradiated by the ultraviolet light source 17 and are firmly arranged on the corresponding LED chip 14. Since the distance A between the outer side surface 1641 of the first part 164 and the corresponding side surface 144 of each the LED chip 14 is equal to the distance H between the upper surface 142 of the LED chip 14 and the corresponding first surface 161 of the fluorescent layer 16, the first parts 164 of the fluorescent layer 16 acts as a conformal coating mounted on the surrounding of the corresponding LED chip 14.

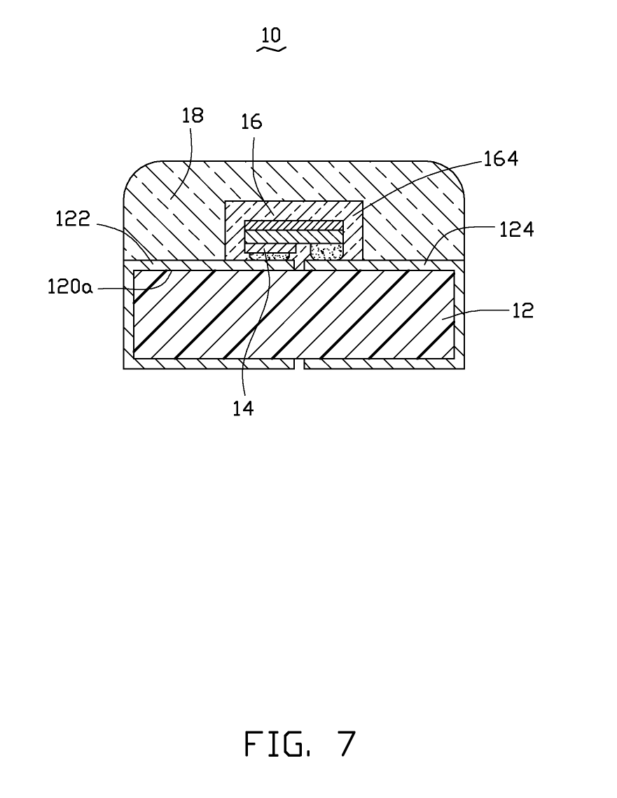

Step 6: referring to FIG. 7, an encapsulant 18 is arranged on the top surface 120a of the substrate 12 and covers the first parts 164 of the fluorescent layer 16 and parts of the first and second electrodes 122, 124. In the present embodiment, the substrate 12 is incised to form two LED packages 10, and the side surface of the encapsulant 14 is coplanar with the outer side surface of the first and second electrodes 122, 124.

It is to be further understood that even though numerous characteristics and advantages have been set forth in the foregoing description of embodiments, together with details of the structures and functions of the embodiments, the disclosure is illustrative only; and that changes may be made in detail, especially in matters of shape, size, and arrangement of parts within the principles of the disclosure to the full extent indicated by the broad general meaning of the terms in which the appended claims are expressed.

What is claimed is:

1. An LED package, comprising:
a substrate;
an LED chip mounted on the substrate, the LED chip having a side surface and an upper surface;
a fluorescent layer evenly distributed over the LED chip; and
an encapsulant covering the fluorescent layer.

2. The LED package of claim 1, wherein the upper surface of the LED chip is planar, and the side surface of the LED chip is perpendicular to the upper surface.

3. The LED package of claim 2, wherein the fluorescent layer has a first surface away from the substrate and an outer side surface perpendicular to the first surface, a distance between the first surface of the fluorescent layer and the upper surface of the LED chip being equal to the distance between the outer side surface of the fluorescent layer and the side surface of the LED chip.

4. A method for manufacturing an LED package, comprising:
providing a substrate;
mounting an LED chip on the substrate;
forming a fluorescent layer on the substrate and covering the LED chip;
providing a patterned mask and an ultraviolet light source, the fluorescent layer comprising a first part just located above and surrounding the LED chip and a second part connected to the first part, the patterned mask being arranged on the second part of the fluorescent layer and exposing the first part of the fluorescent layer, the ultraviolet light source irradiating through the patterned mask to secure the first part of fluorescent layer so that the first part evenly distributing over the LED chip;
removing the patterned mask and the ultraviolet light source;
submerging the substrate, the LED chip and the fluorescent layer into solution to make the second part separated from the substrate; and
forming an encapsulant on the substrate and covering the first part of the fluorescent layer.

5. The method of claim 4, wherein the solution is selected from the group consisting of n-Heptanes, Toluene and Acetone.

6. The method of claim 4, wherein the LED chip comprises an upper surface and a side surface, the upper surface of the LED chip is planar, and the side surface of the LED chip is perpendicular to the upper surface.

7. The method of claim 5, wherein the first part of the fluorescent layer comprises a first surface away from the substrate and an outer side surface perpendicular to the first surface, a distance between the upper surface of the LED chip and the first surface of the fluorescent layer being equal to a distance between the outer side surface of the first part and the side surface of the LED chip.

8. A method for manufacturing a LED package, comprising:
providing a substrate;
mounting a plurality of LED chips on the substrate;
forming a fluorescent layer on the substrate and covering the LED chips;
providing a patterned mask and an ultraviolet light source, the fluorescent layer comprising a plurality of first parts each just located above and surrounding a corresponding LED chip and a plurality of second parts connected to the first parts, the patterned mask having a plurality of holes each exposing a corresponding first part of the fluorescent layer, the ultraviolet light source irradiating through the holes of the patterned mask to secure the first parts of fluorescent layer so that the first parts each evenly distributing over the corresponding LED chip;
removing the patterned mask and the ultraviolet light source;
submerging the substrate, the LED chips, and the fluorescent layer into solution to make the second parts separated from the substrate; and
forming an encapsulant on the substrate and covering the first parts of the fluorescent layer.

9. The method of claim 8, wherein the solution is selected from the group consisting of n-Heptanes, Toluene and Acetone.

10. The method of claim 8, wherein each LED chip comprises an upper surface and a side surface, the upper surface is planar, and the side surface is perpendicular to the upper surface.

11. The method of claim 10, wherein each first part of the fluorescent layer comprises a first surface away from the substrate and an outer side surface perpendicular to the first surface, a distance between the upper surface of the each LED chip and the first surface of the each first part being equal to a distance between the outer side surface of the each first part and the side surface of the each LED chip.

12. The method of claim 8, wherein the substrate is sliced to form a plurality of LED package corresponding to the LED chips.
